(19) United States
(12) Patent Application Publication
(10) Pub. No.: US 2016/0087184 A1
(43) Pub. Date: Mar. 24, 2016

(54) ARRANGEMENT AND CONTROL OF THERMOELECTRIC POWER GENERATION CELLS

(71) Applicant: Nicholas DZUBA, AJAX (CA)

(72) Inventor: Nicholas DZUBA, AJAX (CA)

(21) Appl. No.: 14/847,465

(22) Filed: Sep. 8, 2015

Related U.S. Application Data
(60) Provisional application No. 62/054,577, filed on Sep. 24, 2014.

(51) Int. Cl. H01L 35/32; G21D 1/00; H01L 35/30

(52) U.S. Cl. CPC H01L 35/32; H01L 35/30; G21D 1/006

(57) ABSTRACT

A device is disclosed for generating electricity and is of particular use in the event of a Beyond Design Basis Event at a nuclear power plant. The device includes a first string including a first plurality of thermoelectric generator cells, each of the thermoelectric generator cells of the first plurality operable to generate a voltage and current across a pair of electrical terminals, based upon a temperature differential between two fluids, a second string including a second plurality of thermoelectric generator cells and circuitry adapted to control, dependent upon the temperature differential between the two fluids a switch between a first configuration and a second configuration. In the first configuration the two strings are electrically in parallel and the second configuration, the two strings are electrically in series.

### CROSS-REFERENCE TO RELATED APPLICATIONS

The present application is a continuation application of U.S. Provisional Patent Application No. 62/054,577, filed Sep. 18, 2014, the contents of which are hereby incorporated herein by reference.

### FIELD

The present application relates generally to power generation and, more specifically, to an arrangement and control of thermoelectric power generation cells.

### BACKGROUND

As a result of the 2011 catastrophe at the Fukushima Daiichi Nuclear Power Station, a directive was released by the Canadian Nuclear Safety Commission (CNSC) requiring that all of the Canadian Operated Nuclear Stations re-assess and confirm the safety of their plants. One of the studies requested were to review the power plants' potential vulnerabilities to Beyond Design Basis Events for fuel cooling. Furthermore, the Institute for Radiological Protection and Nuclear Safety is promoting a program called “Hardened Safety core,” which is an additional level of defense to ensure that vital safety functions at nuclear facilities remain operational over a sufficient period of time in the event of a Beyond Design Basis Event.

### BRIEF DESCRIPTION OF THE DRAWINGS

Reference will now be made, by way of example, to the accompanying drawings which show example implementations; and in which:

FIG. 1 illustrates, in block diagram form, a nuclear power generation facility with a Thermoelectric Generator Safety System (TEGSS) in accordance with an aspect of the present application;

FIG. 2 illustrates, in block diagram form, an example implementation of the TEGSS of FIG. 1, including tanks, valves, pumps, heat exchangers and a rack of Thermoelectric Generator (TEG) cells;

FIG. 3 illustrates, in front view, the rack of TEG cells of FIG. 2, in accordance with an embodiment of the present application;

FIG. 4 illustrates, in side view, the rack of TEG cells of FIG. 2, in accordance with an embodiment of the present application;

FIG. 5 illustrates, in top view, the rack of TEG cells of FIG. 2, in accordance with an embodiment of the present application; and

FIG. 6 illustrates a manner of wiring the TEG cells so that multiple configurations may be implemented, in accordance with an embodiment of the present application.

### DETAILED DESCRIPTION

The present application proposes to derived power from a Direct Current power source utilizing Thermo-Electric Generators (TEG's), which obtain power from the heat energy. Conveniently power may be provided in the event of a Beyond Design Basis Event. Indeed, after such an event, heat energy needs to be dissipated. The generated power may be provided to equipment in a control room, or other areas of a nuclear power plant, as required to ensure that a plant status remains available.

Thermoelectric power generation technology is based on the principle of the Seebeck Effect. An electrical potential difference (i.e., a voltage) and a current may be generated, at a thermoelectric power generation (TEG) cell based upon a temperature difference between a hot side and a cold side. The voltage and the current generated by a TEG cell may be seen to increase as the temperature difference (ΔT) between the hot side and the cold side increases. A voltage and a current may be generated by a TEG cell based upon a temperature difference, between the hot side and the cold side, of as little as five degrees.

In an aspect of the present application, a system is proposed with a modular design. With such a modular design, output electric power can be adjusted based upon an output capacity of the heat source. A small scale system can be installed for control and monitoring purposes. In contrast, the system can be increased in size to provide main distribution power for cooling of a nuclear reactor core.

According to an aspect of the present disclosure, there is provided a device for generating electricity. The device includes a first fluid input line carrying a first fluid, a second fluid input line carrying a second fluid, a voltage high line, a voltage low line, a first string including a first plurality of thermoelectric generator cells and a second string including a second plurality of thermoelectric generator cells. Each of the thermoelectric generator cells of the first plurality having a pair of electrical terminals, each of the thermoelectric generator cells of the first plurality individually in fluid communication with the first fluid input line and the second fluid input line, each of the thermoelectric generator cells of the first plurality operable to generate a voltage across the pair of electrical terminals, based upon a temperature differential between the first fluid and the second fluid and the terminals of the first plurality of thermoelectric generator cells connected in series. Each of the thermoelectric generator cells of the second plurality having a pair of electrical terminals, each of the thermoelectric generator cells of the second plurality individually in fluid communication with the first fluid input line and the second fluid input line, each of the thermoelectric generator cells of the second plurality operable to generate a voltage and current across the pair of terminals, based upon the temperature differential between the first fluid and the second fluid, the terminals of the second plurality of thermoelectric generator cells connected in series. The device also includes circuitry adapted to control, dependent upon the temperature differential between the first fluid and the second fluid, a switch between: a first configuration, wherein the first string is connected to the voltage high line and the voltage low line in parallel with the second string; and a second configuration, wherein the first string and the second string are connected, in series, to the voltage high line and to the voltage low line.

Other aspects and features of the present disclosure will become apparent to those of ordinary skill in the art upon review of the following description of specific implementations of the disclosure in conjunction with the accompanying figures.

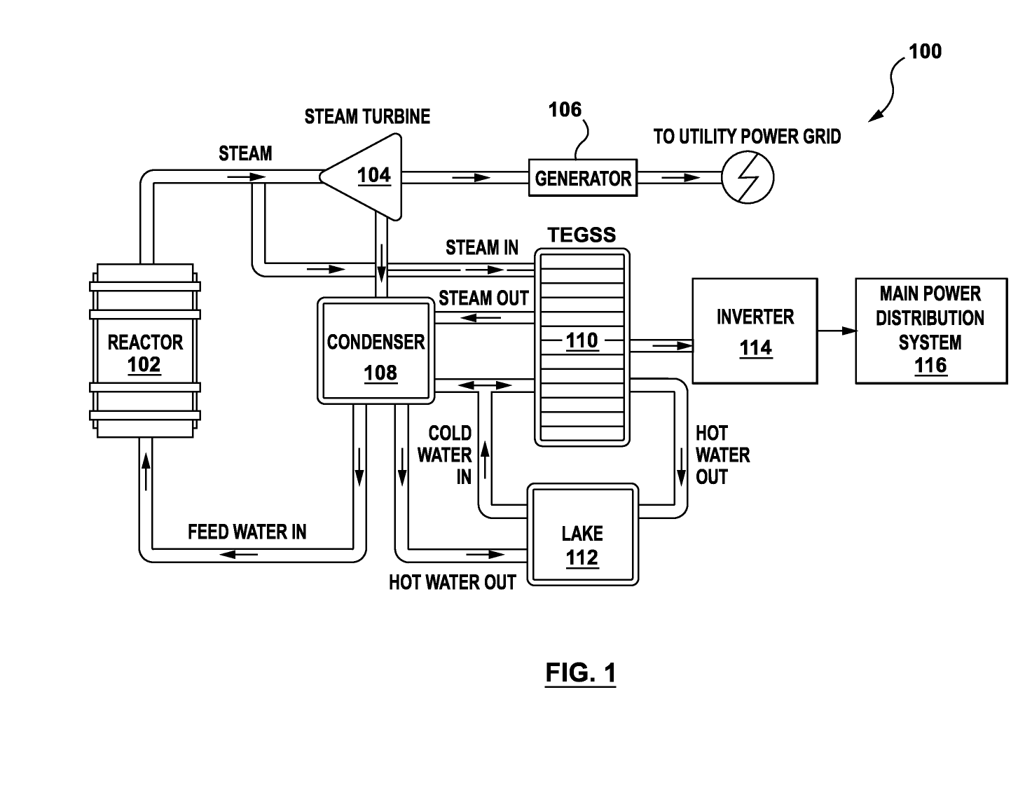

FIG. 1 illustrates, in block diagram form, a nuclear power generation facility 100 that implements aspect of the present application. As is typical, the facility includes a reactor 102, a steam turbine 104, a condenser 108 and a source of cold water. As illustrated in FIG. 1, the source of cold water is a lake 112.

In operation, the reactor 102 receives feed water from the condenser 108. The feed water is heated, through the heat given off by a nuclear reaction occurring within the reactor 102, to form steam. The steam is passed from the reactor 102 to the steam turbine 104. Passage of the steam through the steam turbine 104 allows a generator 106 to generate electricity. The generated electricity is then transferred to a utility power grid. Steam at the output of the steam turbine 104 is received at the condenser 108. In the condenser 108, a received flow of cold water from the source of cold water, e.g., the lake 112, is used to condense the steam back to feed water. The received flow of cold water is heated in during the condensing and returned to the source of the cold water.

In overview, it is proposed herein to add, to the facility 100, a Thermoelectric Generator Safety System (TEGSS) 110.

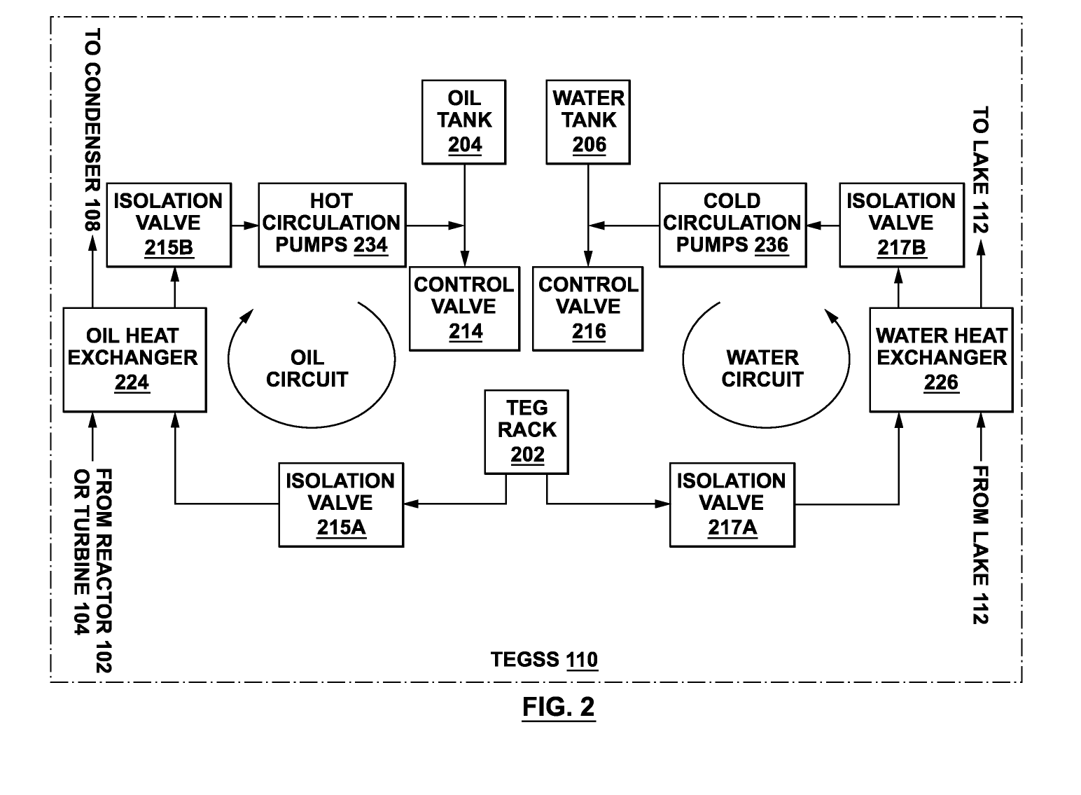

In common with the condenser 108, the TEGSS 110 may receive heat from the reactor steam output after the steam turbine 104. Alternatively, because the steam turbine 104 may not be in operation when the TEGSS 110 is in operation, the TEGSS 110 may receive heat from the reactor steam output before the steam turbine 104. Furthermore, the TEGSS 110 may receive cold water from the lake 112 or other source of cooling water. FIG. 1 illustrates the sources of heat energy and cooling water at a high level. See FIG. 2 for more detail of a typical configuration. Within the TEGSS 110 are a plurality of TEG cells (not shown in FIG. 1). Each TEG cell receives, on the hot side, oil that has been warmed by steam and receives, on the cold side, water that has been cooled by the water from the lake or the other source of cooling water. A voltage and a current is generated, at the TEG cell, based upon a temperature difference between the heated oil and the cooled water.

The voltage and current generated in the TEGSS 110 may be used locally at the facility 100 to, for one non-limiting example, provide power to a main power distribution system 116. In FIG. 1, an inverter 114 is illustrated as an example interface between the TEGSS 110 and the main power distribution system 116 for the facility 100.

FIG. 2 illustrates, in block diagram form, an example implementation of the TEGSS 110 of FIG. 1. Central to the TEGSS 110 is a TEG rack 202. The TEG rack 202 houses at least one TEG cell and, more likely, a plurality of TEG cells (not individually shown). As discussed hereinbefore, the TEG cells generate a voltage and current based upon a temperature difference between the heated oil and the cooled water. The heated oil flows within the TEGSS 110 in an oil circuit. The cooled water flows within the TEGSS 110 in a water circuit. Other configurations may be implemented, depending on the nuclear facility's configuration or type of nuclear facility. For example, one alternative configuration involves connecting the oil heat exchanger 224 directly to the reactor 102 steam outlet. Similarly, the water heat exchanger 226 may be connected to other process systems that circulate cooling water.

As part of the oil circuit, a reservoir, or tank, of oil is associated with a reference number 204. An oil control valve 214 is, on one side, in fluid communication with a part of the oil circuit that includes the oil tank 204, and is, on the other side, in fluid communication with the TEG rack 202. A first oil isolation valve 215A is, on one side, in fluid communication with the TEG rack 202 and is, on the other side, in fluid communication with a oil heat exchanger 224. The oil heat exchanger 224 is also in fluid communication, on one side, with the reactor 102 (or the turbine 104) and, on the other side, with the condenser 108 (see FIG. 1). The oil heat exchanger 224 may also connect directly to the reactor 102 steam output. A second oil isolation valve 215B is, on one side, in fluid communication with the oil heat exchanger 224 and is, on the other side, in fluid communication with a set of hot oil circulation pumps 234. The set of hot oil circulation pumps 234 is, on one side, in fluid communication with the second oil isolation valve 215B and is, on the other side, in fluid communication with the part of the oil circuit that includes the oil tank 204 and the oil control valve 214.

As part of the water circuit, a reservoir, or tank, of water is associated with reference number 206. A water control valve 216 is, on one side, in fluid communication with a part of the water circuit that includes the water tank 206 and is, on the other side, in fluid communication with the TEG rack 202. A first water isolation valve 217A is, on one side, in fluid communication with the TEG rack 202 and is, on the other side, in fluid communication with a water heat exchanger 226. A second water isolation valve 217B is, on one side, in fluid communication with the water heat exchanger 226 and is, on the other side, in fluid communication with a set of cold water circulation pumps 236. The set of cold water circulation pumps 236 is, on one side, in fluid communication with the second water isolation valve 217B and is, on the other side, in fluid communication with the part of the water circuit that includes the water tank 206 and the water control valve 216. Depending on the facility, heating and cooling fluids other than oil or water may be employed.

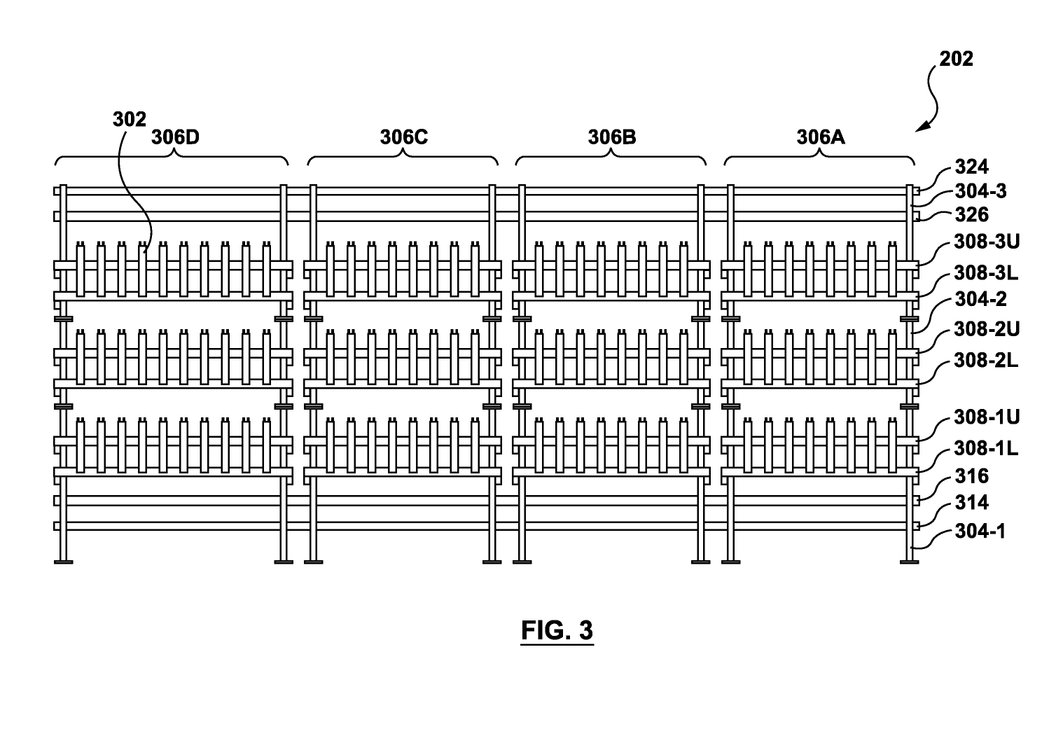

FIG. 3 illustrates, in front view, the TEG rack 202 of FIG. 2 housing a plurality of TEG cells. A representative TEG cell is associated with reference numeral 302. The TEG rack 202 is to be housed within the TEGSS 110 as illustrated in FIG. 2. The TEG rack 202 may include a plurality of rack modules. As illustrated in FIG. 3, the TEG rack 202 includes four rack modules: a first rack module 306A; a second rack module 306B; a third rack module 306C; and a fourth rack module 306D (collectively or individually 306).

An example product suitable for use for the TEG cells 302 is the TEG200-24V from Thermonamic Electronics (Jiangxi) Corp., Ltd. Of Jiangxi, P.R. China. Other TEG cell assemblies may be used to generate power for this system but they will require a different FIGS. 3, 4, 5 assembly configuration. For different assemblies, the process configuration will not be impacted. A person of skill in the art will understand that further suitable commercial TEG cells may exist or may come into existence. Additionally, customized TEG cell assemblies may be developed for specific applications.

As illustrated in FIG. 3, each module 306 comprises three stages: a first stage; a second stage; and a third stage. In each of the first rack module 306A, the second rack module 306B and the third rack module 306C, each stage includes 16 TEG cells 302, eight of which are visible in the front view of FIG. 3. In the fourth rack module 306D, each stage includes 20 TEG cells 302, ten of which are visible in the front view of FIG. 3. This configuration may be altered depending upon the heat source energy and cooling available.

Each stage is defined by a pair of vertical support members and a pair of horizontal support members. A representative ladder-like vertical support member for the first stage of the first rack module 306A is associated with reference numeral 304-1. A representative ladder-like vertical support member for the second stage of the first rack module 306A is associated with reference numeral 304-2. A representative ladder-like vertical support member for the third stage of the first rack module 306A is associated with reference numeral 304-3. Each of the first-module, first-stage vertical support member 304-1, the first-module, second-stage vertical support member 304-2 and the first-module, third-stage vertical support member 304-3 have a counterpart vertical support member at the other end of the first module 306A.

Supporting the TEG cells 302 between the first-module, first-stage vertical support member 304-1 and its counterpart are a first-module, first-stage lower horizontal support member 308-1L and a first-module, first-stage upper horizontal support member 308-1U. Supporting the TEG cells between the first-module, second-stage vertical support member 304-2 and its counterpart are a first-module, second-stage lower horizontal support member 308-2L and a first-module, second-stage upper horizontal support member 308-2U. Supporting the TEG cells between the first-module, third-stage vertical support member 304-3 and its counterpart are a first-module, third-stage lower horizontal support member 308-3L and a first-module, third-stage upper horizontal support member 308-3U.

Also illustrated in FIG. 3 are an oil input line 314 and an oil output line 324. These lines are complemented by a water input line 316 and a water output line 326.

Although not shown in the figures, the water input line 316 is in fluid (water) communication with each TEG cell 302 in the first stage of each of the modules 306. Each of the TEG cells 302 in the first stage of each of the modules 306 is in fluid (water) communication with a corresponding one of the TEG cells 302 in the second stage of each of the modules 306. Each of the TEG cells 302 in the second stage of each of the modules 306 is in fluid (water) communication with a corresponding one of the TEG cells 302 in the third stage of each of the modules 306. Each of the TEG cells 302 in the third stage of each of the modules 306 is in fluid (water) communication with the water output line 326.

Similarly, although not shown in the figures, the oil input line 314 is in fluid (oil) communication with each TEG cell 302 in the first stage of each of the modules 306. Each of the TEG cells 302 in the first stage of each of the modules 306 is in fluid (oil) communication with a corresponding one of the TEG cells 302 in the second stage of each of the modules 306. Each of the TEG cells 302 in the second stage of each of the modules 306 is in fluid (oil) communication with a corresponding one of the TEG cells 302 in the third stage of each of the modules 306. Each of the TEG cells 302 in the third stage of each of the modules 306 is in fluid (oil) communication with the oil output line 324.

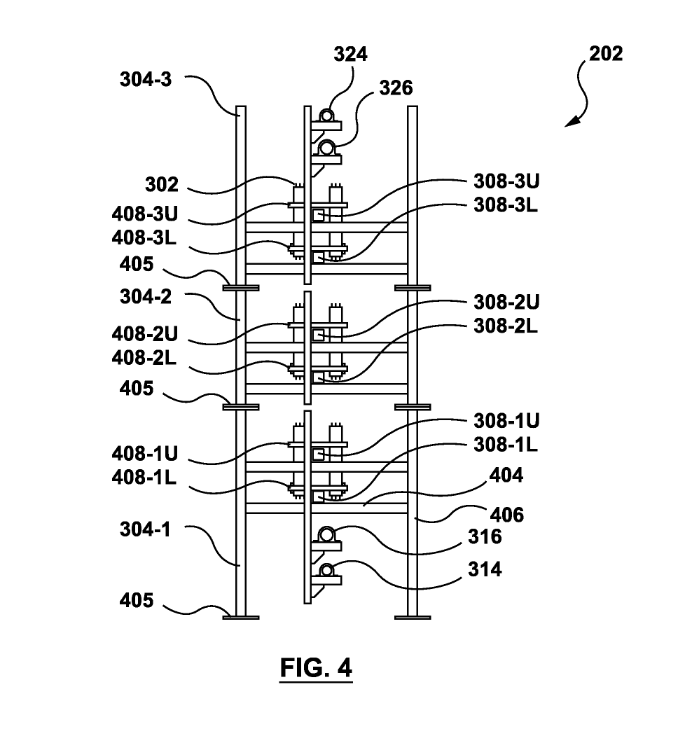

FIG. 4 illustrates the TEG rack 202 in side view. In view of FIG. 4, one can note that the vertical support members 304 may have a ladder-like structure with a pair of cross braces associated connecting a pair of legs in each stage. An exemplary cross brace, for the first module 306A, is associated, in FIG. 4, with reference numeral 404. An exemplary leg, for the first module 306A, is associated, in FIG. 4, with reference numeral 406. The first-module, first-stage vertical support member 304-1 is illustrated, in FIG. 4, as having a flange 405 on the top and bottom of each leg. The first-module, first-stage vertical support member 304-1 is illustrated, in FIG. 4, as having a flange 405 on the top and bottom of each leg 406. The first-module, second-stage vertical support member 304-2 is illustrated, in FIG. 4, as having a flange 405 on the top and bottom of each leg 406. The first-module, third-stage vertical support member 304-3 is illustrated, in FIG. 4, as having a flange 405 on the bottom of each leg 406.

As illustrated in FIG. 4, the TEG cells 302 of distinct strings in a stage are arranged in pairs. Each of the TEG cells 302 is mounted to two crossbars, which are, in turn, mounted to the vertical support members 304. For the first stage of the first module 306, the crossbars illustrated in FIG. 4 are associated with reference numerals 408-1L and 408-1U. For the second stage of the first module 306, the crossbars illustrated in FIG. 4 are associated with reference numerals 408-2L and 408-2U. For the third stage of the first module 306, the crossbars illustrated in FIG. 4 are associated with reference numerals 408-3L and 408-3U.

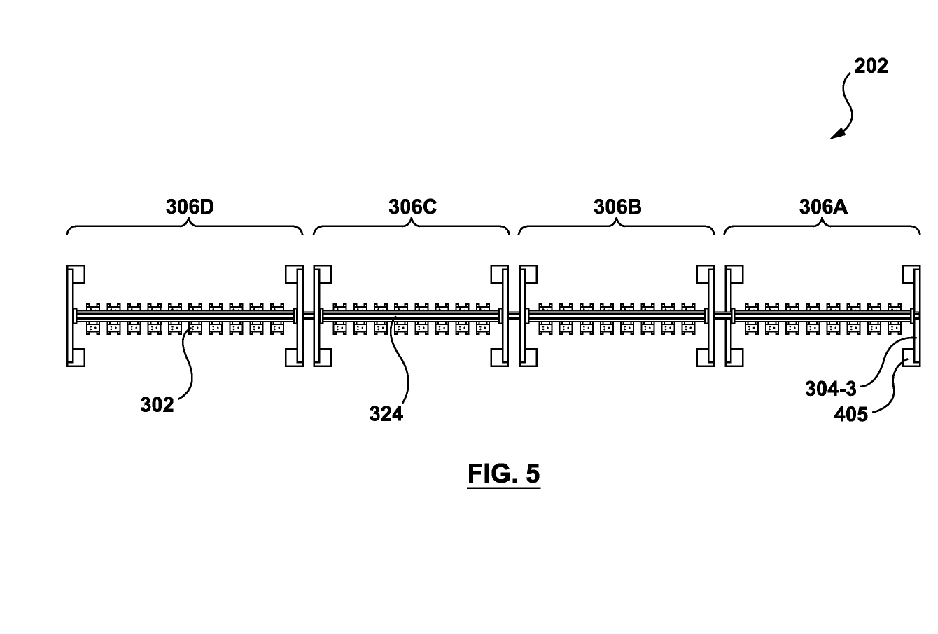

FIG. 5 illustrates the TEG rack 202 in top view. In view of FIG. 5, one can note an example shape of the flanges 405 on the bottoms of the legs 406 of the third-stage vertical support members 304-3.

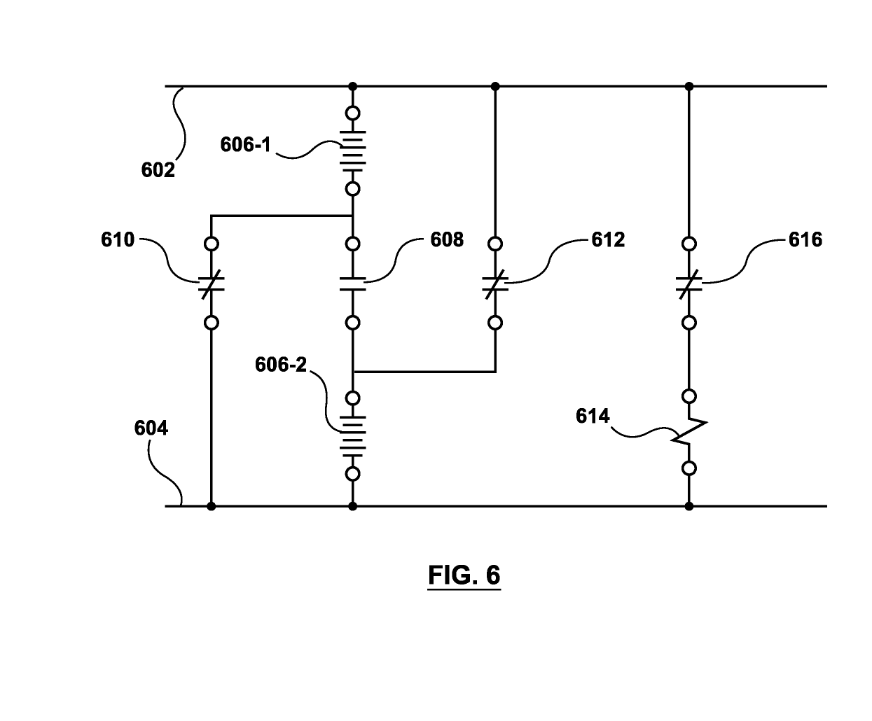

FIG. 6 illustrates a manner of wiring the TEG cells 302 so that multiple configurations may be implemented for efficiently making use of the voltage and current generated by the TEG cells 302. Notably, each of the TEG cells 302 has two electrical terminals across which develops a voltage difference responsive to the temperature difference between the received hot oil and cold water.

The wiring diagram of FIG. 6 includes a voltage high line 602 and a voltage low line 604. A first connection between the voltage high line 602 and the voltage low line 604 includes two strings of TEG cells: a first string 606-1 of TEG cells; and a second string 606-2 of TEG cells.

A “string” 606 of TEG cells relates to a single side of a stage of cells across all modules as depicted in FIG. 5.

For example, the string of TEG cells associated, in FIG. 6, with the reference numeral 606-1 is representative of all 34 TEG cells 302 on the front side of the first stage of the TEG rack 202 (see FIG. 3): eight TEG cells 302 in the first stage of the first rack module 306A; eight TEG cells 302 in the first stage of the second rack module 306B; eight TEG cells 302 in the first stage of the third rack module 306C; and ten TEG cells 302 in the first stage of the fourth rack module 306D. In the first string 606-1 of TEG cells, the terminals of each of the 34 TEG cells 302 are connected in series. The number of TEG cells 302 in series in a stage of a rack is dependent upon the voltage requirements of the distribution bus to which the rack will be connected.

For another example, the string of TEG cells associated, in FIG. 6, with the reference numeral 606-2 is representative of all 34 TEG cells 302 on the back side of the first stage of the TEG rack 202: eight TEG cells 302 in the first stage of the first rack module 306A; eight TEG cells 302 in the first stage of the second rack module 306B; eight TEG cells 302 in the first stage of the third rack module 306C; and ten TEG cells 302 in the first stage of the fourth rack module 306D. In the second string 606-2 of TEG cells, the terminals of each of the 34 TEG cells 302 are connected in series. The number of TEG cells 302 in series in a stage of a rack is dependent upon the voltage requirements of the distribution bus to which the rack will be connected.

The strings 606-1, 606-2 of TEG cells are arranged in series with, and interposed by, an in-line contactor contact 608. While the first string 606-1 of TEG cells connects to the voltage high line 602, the second string 606-2 of TEG cells connects to the voltage low line 604.

A first contactor contact 610 connects a point between the in-line contactor contact 608 and the first string 606-1 of TEG cells to the voltage low line 604.

A second contactor contact 612 connects a point between the in-line contactor contact 608 and the second string 606-2 of TEG cells to the voltage high line 602.

A second connection between the voltage high line 602 and the voltage low line 604, in parallel with the first connection, includes a resistive load 614 and a control contact 616. The resistive load 614 is included in the circuit to limit the open circuit voltage on startup due to high open circuit voltage, which is typical of TEG 302 cells. A suitable contactor for this system configuration would be rated at 1000 VDC with a minimum of two normally open and two normally closed contacts, e.g., Catalogue Number 14-193-100-54-2 from Hubbell Industrial Controls, Inc. of Archdale, N.C. Another suitable control contactor may be selected from among the DPM series control contactors from Eaton Corporation of Cleveland, Ohio. These example contactors come with a selection of different coil voltages that may be used to control the contactor contacts as noted in the following paragraphs. Other coil voltages may be used depending on the system configuration requirements.

Although not illustrated in FIG. 6, a similar circuit exists for a third string and a fourth string across the second stage of all four modules 306. Although not illustrated in FIG. 6, a similar circuit exists for a fifth string and a sixth string across the third stage of all four modules 306.

In operation and in view of FIG. 2, the oil control valve 214 controls a flow of heated oil, from the part of the oil circuit that includes the oil tank 204, into the TEG rack 202. The first oil isolation valve 215A isolates the flow of heated oil, from the TEG rack 202 into the oil heat exchanger 224. At the oil heat exchanger 224, steam is received from the turbine 104 or the reactor 102. After the steam is used to heat the oil received from the first oil isolation valve 215A, the steam is sent to the condenser 108. The second oil isolation valve 215B isolates the flow of heated oil, from the oil heat exchanger 224, into the set of hot oil circulation pumps 234. Oil from the set of hot oil circulation pumps 234 flows back into the part of the oil circuit that includes the oil tank 204 and the oil control valve 214. The isolation valves 215A and 215B may be used to isolate equipment during installation, maintenance, startup and shutdown process activities.

In simultaneous operation, the water control valve 216 controls a flow of cooled water, from the part of the water circuit that includes the water tank 206, into the TEG rack 202. The first water isolation valve 217A isolates the flow of cooled water, from the TEG rack 202 into the water heat exchanger 226. At the water heat exchanger 226, cold water is received from the lake 112 or other cooling source. After the cold water is used to cool the water received from the first water isolation valve 217A, the water is sent back to the lake 112. The second water isolation valve 217B isolates the flow of cooled water, from the water heat exchanger 226, into the set of cold water circulation pumps 236. Water from the set of cold water circulation pumps 236 flows back into the part of the water circuit that includes the water tank 206 and the water control valve 216. The isolation valves 217A and 217B may be used to isolate equipment during installation, maintenance, startup and shutdown process activities.

In operation in view of FIG. 3, the water received from the water control valve 216 is received in the TEG rack 202 on the water input line 316. The water input line 316 passes the received water to each TEG cell 302 in the first stage of each of the modules 306. Each of the TEG cells 302 in the first stage of each of the modules 306 passes the received water to the corresponding one of the TEG cells 302 in the second stage of each of the modules 306. Each of the TEG cells 302 in the second stage of each of the modules 306 passes the received water to the corresponding one of the TEG cells 302 in the third stage of each of the modules 306. Each of the TEG cells 302 in the third stage of each of the modules 306 passes the received water to the water output line 326.

Similarly, in operation in view of FIG. 3, the oil received from the oil control valve 214 is received in the TEG rack 202 on the oil input line 314. The oil input line 314 passes the received oil to each TEG cell 302 in the first stage of each of the modules 306. Each of the TEG cells 302 in the first stage of each of the modules 306 passes the received oil to the corresponding one of the TEG cells 302 in the second stage of each of the modules 306. Each of the TEG cells 302 in the second stage of each of the modules 306 passes the received oil to the corresponding one of the TEG cells 302 in the third stage of each of the modules 306. Each of the TEG cells 302 in the third stage of each of the modules 306 passes the received oil to the oil output line 324.

It has been discussed hereinbefore that a voltage and current may be generated, at each TEG cell 302 based upon a temperature difference between a hot side (oil side) and a cold side (water side). The voltage and current generated by a TEG cell may be seen to decrease as the temperature difference (ΔT) between the hot side and the cold side decreases. Accordingly, the temperature difference (ΔT) may be closely monitored and used to control the configuration of the electrical connections in the TEG rack 202.

In operation in view of FIG. 6, at temperatures differences above a threshold (say, 112 degrees Celsius) for this configuration, the in-line contactor contact 608 is controlled to be open (that is, non-conducting), thereby isolating the first string 606-1 of TEG cells from the second string 606-2 of TEG cells. In this configuration strings 606-1 and 606-2 are connected in parallel. Furthermore, the first contactor contact 610 and the second contactor contact 612 are controlled to be closed (that is, conducting). The control contact 616 is a normally closed contact used to control the system voltage during startup by adding a resistive load due to the high open circuit voltages of the TEG cells 302. The matched resistive load 614 is selected as a suitable load for voltage and current generated at the first string 606-1 of TEG cells and the second string 606-2 of TEG cells for the condition wherein there is 10 degree temperature difference between the oil and the water.

In operation in view of FIG. 6, at temperatures differences below a threshold (say, 112 degrees Celsius), the in-line contactor contact 608 is controlled to be closed (that is, conducting), thereby connecting the first string 606-1 of TEG cells to the second string 606-2 of TEG cells. In this configuration, the first string 606-1 and the second string 606-2 are connected in series. Furthermore, the first contactor contact 610 and the second contactor contact 612 are controlled to be open (that is, non-conducting).

Control for the in-line contactor contact 608, the first contactor contact 610 and the second contactor contact 612 may be provided by a separate circuit (not shown). The separate circuit may include a programmable logic controller (“PLC,” not shown), such as the SIMATIC S7-1200 controller from Siemens of Berlin, Germany. Furthermore, the separate circuit may include multiple circuits that each comprise a control contact in series with a contactor coil. The control contact may be turned on or off by the PLC. Responsive to the PLC turning on the control contact, the associated contactor coil energizes, thereby changing the state (normally-open-to-closed or normally-closed-to-open) of a corresponding contactor contact, e.g., one of the contactor contacts 608, 610, 612 of FIG. 6. The default configuration of this system is for the first string 606-1 and the second string 606-2 to be in a parallel connection. This is done as the system is designed to operate in high heat conditions typical of a nuclear reactor during an emergency event. Alternatively the strings 606-1 and 606-2 can be connected by default in a series connection depending on the configuration of the facility. In order to prevent a short circuit condition between the voltage high line 602 and the voltage low line 604, the PLC may be programmed to introduce a time delay when controlling the contactor contacts 608 and 610/612 to change state, e.g., when controlling a change from a parallel connection to a series connection, the PLC may control the first contactor contact 610 and the second contactor contact 612 to first change state to open (that is, non-conducting) and the PLC may then control the in-line contactor contact 608 to change state to closed (that is, conducting).

In a similar manner, voltages may be generated across serialized terminals in the third string and the fourth string, which may be controlled to be in serial or parallel based upon the temperature difference relative to the threshold.

In a similar manner, voltages may be generated across serialized terminals in the fifth string and the sixth string, which may be controlled to be in serial or parallel based upon the temperature difference relative to the threshold.

The threshold of 112 degrees Celsius above is based on the configuration of 34 TEG cells 302 in series. If the TEG cells 302 in series are changed, to provide an alternative system configuration, the 112 degrees Celsius threshold may also change. This threshold is dependent upon the model selected for the inverter 114 model that is to act as an interface between the TEG rack 202 of the TEGSS 110 and the main power distribution system 116 of the facility 100 (see FIG. 1).

Conveniently, the illustrated example TEG rack 202 has two configurations: a first configuration with three stages of two strings of 34 series-connected TEG cells 302 in parallel; and a second configuration with three stages of two strings of 68 series-connected TEG cells 302. Under predetermined conditions, various contactor coils (e.g., 608, 610, 612) may act to switch from the first configuration to the second configuration. Such switching may be seen to keep the inverter 114 operational on startup or when the TEGSS 110 is experiencing a transient, or shutdown.

As will be clear to a person of ordinary skill in the art, although the operation of the TEGSS 110 has been described herein in the context of switching two strings of series-connected TEG cells 302 between parallel and series configurations. Other configurations may feature three, four or more strings of series-connected TEG cells 302 being controlled between parallel and series configurations. Indeed, when four strings of series-connected TEG cells 302 are employed there may be intermediate steps between all four in series and all four in parallel. Furthermore, configuration options may exist that eschew switching between parallel and series configurations.

Furthermore, the absence of mechanical moving parts for the TEG rack 202 to generate the voltage and current may be seen to establish an ease of maintenance. Such an ease of maintenance may be seen to reduce overhead cost compared to conventional power generation technology. Beneficially, the TEG rack 202 may be viewed as being environmentally friendly since, in operation, the TEG rack 202 releases no greenhouse gasses to the environment.

The above-described implementations of the present application are intended to be examples only. Alterations, modifications and variations may be effected to the particular implementations by those skilled in the art without departing from the scope of the application, which is defined by the claims appended hereto.

What is claimed is:

1. A device for generating electricity comprising:
a first fluid input line carrying a first fluid;
a second fluid input line carrying a second fluid;
a voltage high line;
a voltage low line;
a first string including a first plurality of thermoelectric generator cells,
each of the thermoelectric generator cells of the first plurality having a pair of electrical terminals,
each of the thermoelectric generator cells of the first plurality individually in fluid communication with the first fluid input line and the second fluid input line,
each of the thermoelectric generator cells of the first plurality operable to generate a voltage across the pair of electrical terminals, based upon a temperature differential between the first fluid and the second fluid,
the terminals of the first plurality of thermoelectric generator cells connected in series; and
a second string including a second plurality of thermoelectric generator cells,
each of the thermoelectric generator cells of the second plurality having a pair of electrical terminals,
each of the thermoelectric generator cells of the second plurality individually in fluid communication with the first fluid input line and the second fluid input line,
each of the thermoelectric generator cells of the second plurality operable to generate a voltage and current across the pair of terminals, based upon the temperature differential between the first fluid and the second fluid,
the terminals of the second plurality of thermoelectric generator cells connected in series; and
circuitry adapted to control, dependent upon the temperature differential between the first fluid and the second fluid, a switch between:
a first configuration, wherein the first string is connected to the voltage high line and the voltage low line in parallel with the second string; and
a second configuration, wherein the first string and the second string are connected, in series, to the voltage high line and to the voltage low line.

2. The device of claim 1 wherein the first string and the second string form a first stage, further comprising a second stage formed from:
a third string including a third plurality of thermoelectric generator cells,
each of the thermoelectric generator cells of the third plurality having a pair of electrical terminals,
each of the thermoelectric generator cells of the third plurality in fluid communication with a corresponding one of thermoelectric generator cells of the first plurality to individually receive the first fluid and the second fluid,
each of the thermoelectric generator cells of the third plurality operable to generate a voltage and current across the pair of terminals, based upon the temperature differential between the first fluid and the second fluid,
the terminals of the third plurality of thermoelectric generator cells connected in series; and
a fourth string including a fourth plurality of thermoelectric generator cells,
each of the thermoelectric generator cells of the fourth plurality having a pair of electrical terminals,
each of the thermoelectric generator cells of the fourth plurality in fluid communication with a corresponding one of thermoelectric generator cells of the second plurality to individually receive the first fluid and the second fluid,
each of the thermoelectric generator cells of the fourth plurality operable to generate a voltage and current across the pair of terminals, based upon the temperature differential between the first fluid and the second fluid,
the terminals of the fourth plurality of thermoelectric generator cells connected in series.

3. The device of claim 2 further comprising a third stage formed from:
a fifth string including a fifth plurality of thermoelectric generator cells,
each of the thermoelectric generator cells of the fifth plurality having a pair of electrical terminals,
each of the thermoelectric generator cells of the fifth plurality in fluid communication with a corresponding one of thermoelectric generator cells of the third plurality to individually receive the first fluid and the second fluid,
each of the thermoelectric generator cells of the fifth plurality operable to generate a voltage and current across the pair of terminals, based upon the temperature differential between the first fluid and the second fluid,
the terminals of the fifth plurality of thermoelectric generator cells connected in series; and
a sixth string including a sixth plurality of thermoelectric generator cells,
each of the thermoelectric generator cells of the sixth plurality having a pair of electrical terminals,
each of the thermoelectric generator cells of the sixth plurality in fluid communication with a corresponding one of thermoelectric generator cells of the fourth plurality to individually receive the first fluid and the second fluid,
each of the thermoelectric generator cells of the sixth plurality operable to generate a voltage and current across the pair of terminals, based upon the temperature differential between the first fluid and the second fluid,
the terminals of the sixth plurality of thermoelectric generator cells connected in series.

4. The device of claim 1 wherein the circuitry comprises a contactor contact operable to electrically connect the first string to the second string in the second configuration.

5. The device of claim 1 wherein the circuitry comprises a contactor contact operable to electrically connect the first string to the voltage low line in the first configuration.

6. The device of claim 1 wherein the circuitry comprises a contactor contact operable to electrically connect the second string to the voltage high line in the first configuration.

7. The device of claim 1 wherein the first fluid is an oil or other heat transfer liquid suitable for the application temperature ranges of the process or facility.

8. The device of claim 1 wherein the second fluid is water or other heat transfer liquid suitable for the application temperature ranges of the process or facility.

9. A fluid circuit comprising:
the device as recited in claim 1;
a first tank for holding the first liquid;
a first heat exchanger, in fluid communication with the device, adapted to transfer heat to the first liquid from a secondary fluid;
a first liquid control valve, in fluid communication with the first heat exchanger, adapted to control flow of the first liquid into the device from the first heat exchanger and the first tank;
a second tank for holding the second liquid;
a second heat exchanger, in fluid communication with the device, adapted to transfer heat to a tertiary fluid from the second liquid; and
a second liquid control valve, in fluid communication with the second heat exchanger, adapted to control flow of the second liquid into the device from the second heat exchanger and the second tank.

10. A system comprising:
the fluid circuit recited in claim 9;
a reactor adapted to receive liquid feed water and output steam;
a steam turbine adapted to receive the steam and to release output steam; and
a condenser adapted to receive the output steam, the secondary fluid from the fluid circuit and the second liquid and to release the feed water and the secondary fluid;
wherein the fluid circuit is adapted to receive the output steam.
